(19) United States
(12) Patent Application Publication
(10) Pub. No.: US 2024/0196532 A1
(43) Pub. Date: Jun. 13, 2024

(54) PRINTED CIRCUIT BOARD AND MANUFACTURING METHOD THEREOF

(71) Applicant: Samsung Electro-Mechanics Co., Ltd., Suwon-si (KR)

(72) Inventor: Kyehwan Lee, Suwon-si (KR)

(73) Assignee: Samsung Electro-Mechanics Co., Ltd., Suwon-si (KR)

(21) Appl. No.: 18/199,071

(22) Filed: May 18, 2023

(30) Foreign Application Priority Data
Dec. 9, 2022 (KR) 10-2022-0171532

(51) Int. Cl. H05K 1/11; H05K 3/40

(52) U.S. Cl. CPC H05K 1/113; H05K 3/4007; H05K 1/09

(57) ABSTRACT

A printed circuit board includes an insulation layer having a first surface and a second surface which are opposite to each other, a first connection pad which is embedded in the insulation layer and has a surface recessed from the first surface of the insulation layer, a conductive layer which is located on the first connection pad and has a part embedded in the insulation layer and another part protruding from the first surface of the insulation layer, and a first solder resist layer which is located on the first surface of the insulation layer and has a surface which is at a level equal to or lower than a surface of the conductive layer.

### CROSS-REFERENCE TO RELATED APPLICATION

This application claims priority to and the benefit of Korean Patent Application No. 10-2022-0171532 filed in the Korean Intellectual Property Office on Dec. 9, 2022, the entire contents of which are incorporated herein by reference.

### BACKGROUND

### 1. Field

The present disclosure relates to a printed circuit board and a manufacturing method thereof.

### 2. Description of the Related Art

As the performance of the electronic devices gradually improves in accordance with the development of the electronic industry, the semiconductor package is demanded to be down-sized/thinner and high-density. As the number of mounted ICs is increased for the high density of the package, the number of I/O connection terminals is increased so that a process ability for implementing a microcircuit with a reduced bonding pad interval needs to be ensured.

As an IC mounting method in the current high density package, a wire bonding method and a flip bonding method are used. When the number of I/O connection terminals is increased to a predetermined level or higher, a cost consumed for the mounting is considered so that the flip bonding method is preferred. However, even when a wire bonding chip is mounted, a bond finger implemented with a microcircuit is necessary and it is necessary to ensure the appropriate thickness of a nickel conductive layer to be equipped with a wire bonding environment.

The above information disclosed in this Background section is only for enhancement of understanding of the background of the described technology, and therefore it may contain information that does not form the prior art that is already known in this country to a person of ordinary skill in the art.

### SUMMARY

The described technology has been made in an effort to provide a printed circuit board which ensures a conductive layer thickness appropriate for a wire bonding environment while implementing a bond finger for mounting a wire bonding chip with a microcircuit and a manufacturing method thereof

However, the object to be achieved by the embodiments is not limited to the above-described object, but may be expanded in various manners within the range of the technical spirit included in the present disclosure.

According to an embodiment, a printed circuit board includes an insulation layer having a first surface and a second surface which are opposite to each other, a first connection pad which is embedded in the insulation layer and has a surface recessed from the first surface of the insulation layer, a conductive layer which is located on the first connection pad and has a part embedded in the insulation layer and another part protruding from the first surface of the insulation layer, and a first solder resist layer which is located on the first surface of the insulation layer and has a surface which is at a level equal to or lower than a surface of the conductive layer.

A side surface of the conductive layer has a part which is in contact with the first solder resist layer.

The conductive layer protrudes from the surface of the first solder resist layer and a thickness of a part of the conductive layer that protrudes from the surface of the first solder resist layer is larger than a thickness of the first solder resist layer.

The conductive layer further includes a nickel (Ni) conductive layer located on the first connection pad and a gold (Au) conductive layer located on the nickel (Ni) conductive layer and the nickel conductive layer is in contact with the first connection pad at a height lower than the first surface of the insulation layer.

A thickness of the nickel conductive layer is larger than a thickness of the first solder resist layer.

The nickel conductive layer protrudes from the surface of the first solder resist layer.

A width of the conductive layer is equal to a width of the first connection pad in a portion where the conductive layer is in contact with the first connection pad.

A width of a part of the conductive layer embedded in the first solder resist layer and a width of a part of the conductive layer protruding from the first solder resist layer are equal to each other.

The conductive layer further includes a nickel (Ni) conductive layer located on the first connection pad and a gold (Au) conductive layer located on the nickel (Ni) conductive layer and a width of the gold conductive layer is equal to a width of the nickel conductive layer.

The conductive layer further includes a palladium (Pd) conductive layer disposed between the nickel conductive layer and the gold conductive layer, and includes another palladium (Pd) conductive layer disposed between the nickel conductive layer and the first connection pad.

A width of the part of the conductive layer embedded in the insulation layer is smaller than a width of the part of the conductive layer protruding from the first surface of the insulation layer.

A width of the part of the conductive layer protruding from the first surface of the insulation layer increases from both side surfaces of the part of the conductive layer embedded in the insulation layer.

A width of the part of the conductive layer protruding from the first surface of the insulation layer increases from one side surface of the part of the conductive layer embedded in the insulation layer, and another side surface opposing the one side surface of the part of the conductive layer embedded in the insulation layer is coplanar with a side surface of the part of the conductive layer protruding from the first surface of the insulation layer.

The insulation layer includes a groove adjacent to a side surface of the part of the conductive layer embedded in the insulation layer, and a portion of the first solder resist layer fills a space of the groove.

The insulation layer includes a pair of grooves adjacent to both side surfaces of the part of the conductive layer embedded in the insulation layer, and portions of the first solder resist layer fill spaces of the pair of grooves.

The conductive layer is formed in plural such that the plurality of conductive layers are disposed on the insulation layer to be adjacent to each other, and a portion of the first solder resist layer is disposed between the plurality of adjacent conductive layers.

The first connection pad is a bond finger for a wire bonding pad.

The printed circuit board for a semiconductor package further includes: a second connection pad located on the second surface of the insulation layer, and a second solder resist layer which is disposed in the vicinity of the second connection pad on the second surface of the insulation layer.

The first solder resist layer is thinner than the second solder resist layer.

The insulation layer includes a plurality of insulation layers and each of the plurality of insulation layers includes a circuit layer.

The printed circuit board further includes a via which is embedded in the insulation layer to be connected to the circuit layer and extends in a thickness direction of the insulation layer.

According to another embodiment, a printed circuit board includes an insulation layer having a first surface and a second surface which are opposite to each other; a first connection pad embedded in the insulation layer; a second connection pad disposed on the second surface of the insulation layer and connected to the first connection pad through a via; a first conductive layer disposed on the first connection pad; a second conductive layer disposed on the second connection pad; a first solder resist layer disposed on the first surface of the insulation layer; and a second solder resist layer disposed on the second surface of the insulation layer. At least a portion of a side surface of the first conductive layer is exposed from an upper surface of the first solder resist layer.

An upper surface of the first connection pad is recessed from the first surface of the insulation layer.

At least a portion of the first solder resist layer is disposed between an inner surface of a recess of the insulation layer and a side surface of the nickel (Ni) conductive layer.

The nickel (Ni) conductive layer includes a first portion embedded in the insulation layer and a second portion protruding from the first surface of the insulation layer, and a width of the first portion of the nickel (Ni) conductive layer is less than or equal to a width of the second portion of the nickel (Ni) conductive layer, where each width is measured in a direction orthogonal to a stacking direction.

According to still another embodiment, a printed circuit board includes an insulation layer having a first surface and a second surface which are opposite to each other; a first connection pad embedded in the insulation layer; a second connection pad disposed on the second surface of the insulation layer and connected to the first connection pad through a via; a first conductive layer disposed on the first connection pad; a second conductive layer disposed on the second connection pad; a first solder resist layer disposed on the first surface of the insulation layer; and a second solder resist layer disposed on the second surface of the insulation layer. At least a portion of a side surface of the first conductive layer is exposed from an upper surface of the first solder resist layer.

No portion of a side surface of the second conductive layer is exposed from a lower surface of the second solder resist layer.

Each of the first and second conductive layers comprises a nickel (Ni) conductive layer disposed on the first connection pad and a gold (Au) conductive layer disposed on the nickel (Ni) conductive layer, and a portion of the nickel (Ni) conductive layer is embedded in the insulation layer and another portion of the nickel (Ni) conductive layer protrudes from the upper surface of the first solder resist layer.

A thickness of the nickel (Ni) conductive layer of the first conductive layer is greater than a thickness of the nickel (Ni) conductive layer of the second conductive layer, where each thickness is measured in a stacking direction.

A width of the first conductive layer is smaller than a width of the second conductive layer, where each width is measured in a direction orthogonal to a stacking direction.

A thickness of the first solder resist layer is smaller than a thickness of the second solder resist layer, where each thickness is measured in a stacking direction.

According to yet another embodiment, a manufacturing method of a printed circuit board includes: forming an embedded pattern substrate including a first connection pad embedded in an insulation layer having a first surface and a second surface which are opposite to each other, forming a first solder resist layer on the first surface of the insulation layer to cover the first connection pad, patterning a first opening in the first solder resist layer to expose the first connection pad, forming a conductive layer in the first opening by performing a plating process, and thinning the first solder resist layer.

The thinning of the first solder resist layer includes protruding the conductive layer from a surface of the first solder resist layer.

A thickness of a part of the conductive layer that protrudes from the surface of the first solder resist layer is formed to be larger than a thickness of the first solder resist layer.

The forming of a conductive layer includes forming a nickel (Ni) conductive layer on the first connection pad; and forming a gold (Au) conductive layer on the nickel conductive layer.

The thinning of the first solder resist layer includes making a thickness of the nickel conductive layer larger than a thickness of the first solder resist layer.

The thinning of the first solder resist layer includes protruding the nickel conductive layer from a surface of the first solder resist layer.

The pattering of the first opening on the first solder resist layer includes forming a plurality of first openings to be adjacent to each other.

The thinning of the first solder resist layer includes thinning the first solder resist layer by a physical process using laser.

The thinning of the first solder resist layer includes thinning the first solder resist layer by a chemical process using chemicals.

According to the manufacturing method of a printed circuit board according to the embodiment, a conductive layer thickness suitable for the wire bonding environment may be ensured while implementing a bond finger for mounting a wire bonding chip by a microcircuit.

That is, when the wire bonding substrate is manufactured by an embedded trace substrate (ETS) process, the solder resist layer may be supported by a dam in the vicinity of the conductive layer formed on the connection pad. Accordingly, even though the gold plating is performed above the connection pad, the overhanging is prevented to sufficiently ensure an interval in the bond finger region.

Thereafter, the height of the connection pad which is a bond finger may protrude to be higher than the solder resist layer by thinning the solder resist layer. Accordingly, the process may be performed without causing the interference of a capillary tool during the wire bonding.

### BRIEF DESCRIPTION OF THE DRAWINGS

FIG. 1 is a cross-sectional view illustrating a printed circuit board according to an embodiment.

FIG. 2 is a cross-sectional view illustrating a modified example of a printed circuit board illustrated in FIG. 1.

FIGS. 3, 4, 5, and 6 are cross-sectional views illustrating various modified examples of a printed circuit board illustrated in FIG. 1.

FIG. 7 is a cross-sectional view illustrating a printed circuit board according to another embodiment.

FIGS. 8, 9, 10, and 11 are cross-sectional views illustrating various modified examples of a printed circuit board illustrated in FIG. 7.

FIG. 12 is a cross-sectional view illustrating a printed circuit board according to still another embodiment.

FIGS. 13A through 13G are cross-sectional views illustrating a part of a process for manufacturing a printed circuit board illustrated in FIG. 1.

FIGS. 14A through 14E are cross-sectional views illustrating the other part of a process for manufacturing a printed circuit board illustrated in FIG. 1.

### DETAILED DESCRIPTION

Hereinafter, embodiments will be described with reference to the accompanying drawings to be easily carried out by those skilled in the art. The drawings and description are to be regarded as illustrative in nature and not restrictive. Like reference numerals designate like elements throughout the specification. Further, in the accompanying drawings, some components are exaggerated, omitted, or schematically illustrated and a size of each component does not entirely reflect the actual size.

Further, the accompanying drawings are provided for easy understanding of the embodiment disclosed in the present specification, but the technical spirit disclosed in the present disclosure is not limited by the accompanying drawings. It should be understood that all changes, equivalents, and alternatives included in the spirit and the technical scope of the present disclosure are included.

Terms including ordinal numbers such as first or second may be used to describe various constituent elements, but the constituent element is not limited by the terms. These terms may be used to distinguish one constituent element from the other constituent element.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, to be located “above” or “on” a reference part means to be located above or below the reference part and not necessarily to be located “above” or “on” in an opposite direction to the gravity.

Throughout the specification, terms such as “include” or “have” are intended to designate that a feature, number, step, operation, component, part, or combination thereof described in the specification is present, but it should be understood that this does not preclude the possibility of addition or existence of one or more other features or numbers, steps, operations, components, parts, or combinations thereof. Accordingly, unless explicitly described to the contrary, the word “comprise” and variations such as “comprises” or “comprising”, will be understood to imply the inclusion of stated elements but not the exclusion of any other elements.

Further, in the entire specification, the word “on a flat surface” means when an object portion is viewed from the above, and the word “on a cross section” means when a cross section taken by vertically cutting an object portion is viewed from the side.

Further, throughout the specification, “connected” not only means that two or more components are directly connected, but also means that two or more components are indirectly connected with the other component therebetween, physically connected, and electrically connected, or referred to as different names according to the position of the function, but means to be integrated.

Through the specification, a substrate has a structure which is wide on a plan view and is thin in a cross-sectional view and a “planar direction of a substrate” means a direction parallel to a wide and flat surface of the substrate and a “thickness direction of the substrate” means a direction which is vertical to a wide and flat surface of the substrate and parallel to a stacking direction of layers.

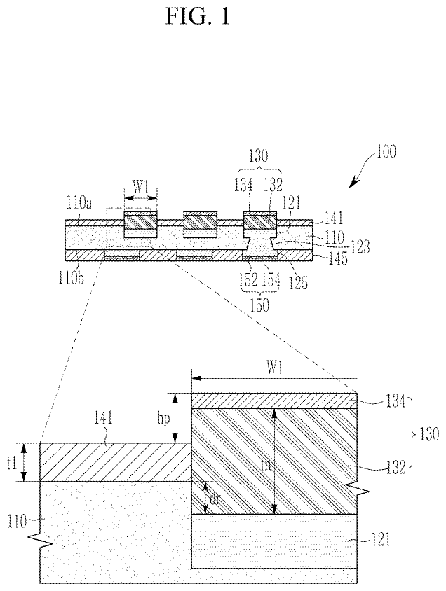

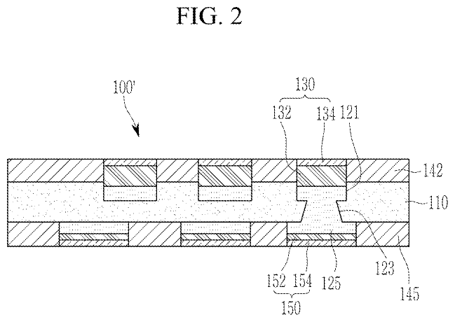

FIG. 1 is a cross-sectional view illustrating a printed circuit board according to an embodiment, and FIG. 2 is a cross-sectional view illustrating a modified example of a printed circuit board illustrated in FIG. 1.

Referring to FIG. 1, a printed circuit board 100 according to the present embodiment includes an insulation layer 110 and a first connection pad 121 embedded in the insulation layer 110. The insulation layer 110 and the first connection pad 121 configure an embedded pattern substrate. The printed circuit board 100 may be used for a semiconductor package.

The insulation layer 110 has a first surface 110a and a second surface 110b which are opposite to each other. The first connection pad 121 is embedded in the insulation layer 110. In this case, the first connection pad 121 has a surface which is recessed from the first surface 110a of the insulation layer 110. The first connection pad 121 includes a copper (Cu) layer.

The insulation layer 110 includes a resin insulation layer. The insulation layer 110 uses a thermosetting resin such as epoxy resin, a thermoplastic resin such as polyimide, or a resin impregnated with a reinforcing member such as glass fiber or inorganic filler, for example, prepreg, and also includes a thermosetting resin and/or a photocurable resin, but is not limited thereto.

A conductive layer 130 may be formed on the first connection pad 121, and the conductive layer 130 includes a nickel (Ni) conductive layer 132 and a gold (Au) conductive layer 134. The nickel conductive layer 132 is formed on the first connection pad 121 and the gold conductive layer 134 is formed on the nickel conductive layer 132. The nickel conductive layer 132 may be formed to be thicker than the gold conductive layer 134.

In the present embodiment, the conductive layer 130 may be formed by an electrolytic gold plating method. That is, the nickel conductive layer 132 and the gold conductive layer 134 may be formed by applying a current to the first connection pad 121 including copper to form a nickel/gold metal film. Further, a part of the conductive layer 130 is embedded in the insulation layer 110 and another part of the conductive layer 130 protrudes from a first surface 110a of the insulation layer 110.

A first solder resist layer 141 may be formed on the first surface 110a of the insulation layer 110. An upper surface of the first solder resist layer 141 may be lower than a surface of the conductive layer 130. That is, the conductive layer 130 may protrude from the upper surface of the first solder resist layer 141, and at least a portion of a side surface of the conductive layer 130 may be exposed from the upper surface of the first solder resist layer 141. In this case, a protruding thickness hp of the conductive layer 130 may be formed to be larger than a thickness t1 of the first solder resist layer 141. For example, a protruding height hp of the conductive layer 130 may be 3 μm or larger.

A side surface of the conductive layer 130 may have a part which is in contact with the first solder resist layer 141. A part of the conductive layer 130 protruding from the insulation layer 110 may be in contact with a side surface of the first solder resist layer 141.

The nickel conductive layer 132 may be formed to be in contact with the first connection pad 121 at a lower height than the first surface 110a of the insulation layer 110. One surface of the first connection pad 121 is disposed to be recessed from the first surface 110a of the insulation layer 110 so that the nickel conductive layer 132 plated thereon may be formed by forming an interface with the first connection pad 121 at a lower position than the first surface 110a of the insulation layer 110.

A thickness tn of the nickel conductive layer 132 formed as described above may be formed to be larger than a thickness t1 of the first solder resist layer 141. In addition, the nickel conductive layer 132 may be formed to protrude from the surface of the first solder resist layer 141 to be higher than the surface. For example, the thickness tn of the nickel conductive layer 132 may be formed to be 7 μm or larger.

A side surface of the nickel conductive layer 132 may have a part which is in contact with the first solder resist layer 141. A part of the nickel conductive layer 132 protruding from the insulation layer 110 may be in contact with the side surface of the first solder resist layer 141.

In the meantime, when the printed circuit board 100 is seen from the cross-section cut in a thickness direction, a width of the conductive layer 130 may be formed to be the same as a width of the first connection pad 121 at a part where the conductive layer 130 is in contact with the first connection pad 121. Further, a width of a part of the conductive layer 130 which is embedded in the first solder resist layer 141 may be same as a width of a part of the conductive layer 130 which protrudes from the first solder resist layer 141. Accordingly, the conductive layer 130 may be formed so as not to exceed a width of a part of the conductive layer 130 embedded in the first solder resist layer 141 in a planar direction of the substrate in an upper portion of the first solder resist layer 141.

Specifically, a region which is recessed from the first surface 110a of the insulation layer 110 on the first connection pad 121 with a recessed depth dr and a region formed thereon to form a boundary with the first solder resist layer 141 may be formed to align the interfaces thereof. The nickel conductive layer 132 is formed in this region and the nickel conductive layer 132 is formed to have the same width W1 as the first connection pad 121. Further, also in the relationship of the nickel conductive layer 132 and the gold conductive layer 134 which configure the conductive layer 130, the gold conductive layer 134 may be formed to have the same width W1 as the nickel conductive layer 132.

The printed circuit board 100 according to the present embodiment includes a plurality of conductive layers 130 on the insulation layer 110 and the plurality of conductive layers 130 is aligned to be adjacent to each other in a planar direction of the substrate. The first solder resist layer 141 is formed between the plurality of adjacent conductive layers 130. That is, the first solder resist layer 141 may be interposed to isolate the plurality of adjacent conductive layers 130 from each other.

The insulation layer 110 includes a wire bonding pad having a bond finger region. In this case, the first connection pad 121 configures the bond finger of the bond finger region and the plurality of first connection pads 121 forms a plurality of bond fingers. That is, the first connection pad 121 configures a bond finger for a wire bonding pad and thus, a conductive wire is bonded to the first connection pad 121 when the semiconductor chip is wire-bonded.

A second connection pad 125 is further formed on a second surface 110b of the insulation layer 110. A second solder resist layer 145 is formed in vicinity of the second connection pad 125 on the second surface 110b of the insulation layer 110. In this case, the first solder resist layer 141 may be formed to be thinner than the second solder resist layer 145. Further, a via 123 is formed to be embedded in the insulation layer 110 and the via 123 may be configured to connect the first connection pad 121 and the second connection pad 125.

The second connection pad 125 includes a copper (Cu) layer and the conductive layer 150 is formed on the second connection pad 125. The conductive layer 150 includes the nickel (Ni) conductive layer 152 and the gold (Au) conductive layer 154. The nickel conductive layer 152 is formed on the second connection pad 125 and the gold conductive layer 154 is formed on the nickel conductive layer 152. In one embodiment, no portion of a side surface of the conductive layer 150 may be exposed from a lower surface of the second solder resist layer 145.

In one embodiment, a width of the conductive layer 130 may be smaller than a width of the conductive layer 150, where each width is measured in a direction orthogonal to a stacking direction.

A plurality of second connection pads 125 may be aligned on the second surface 110b of the insulation layer 110 to be adjacent to each other. The second solder resist layer 145 may be formed between the plurality of adjacent second connection pad 125. That is, the second solder resist layer 145 is interposed to isolate the plurality of adjacent second connection pads 125 from each other.

In the above description, an embodiment in which the conductive layer 130 of the printed circuit board 100 is formed to protrude from the surface of the first solder resist layer 141 has been described with reference to FIG. 1. As another example, a surface of the first solder resist layer 142 of the printed circuit board 100′ may have an equal height to the conductive layer as shown in FIG. 2, which is also included in the scope of the present disclosure. This is the same as in another embodiment and a modified example.

Further, FIG. 1 illustrates the printed circuit board 100 having a structure with connection pads 121 and 125 on both surfaces of the insulation layer 110, but the second connection pad 125 disposed on the second surface 110b of the insulation layer 110 may be omitted, which also belongs to the range of the present disclosure. This is the same as in another embodiment and a modified example.

Moreover, the insulation layer 110 includes a plurality of insulation layers and each of the plurality of insulation layers includes a circuit layer. Accordingly, the circuit layer is formed on each of three or more insulating layers and a via extends in a thickness direction of the insulation layer to connect the circuit layers.

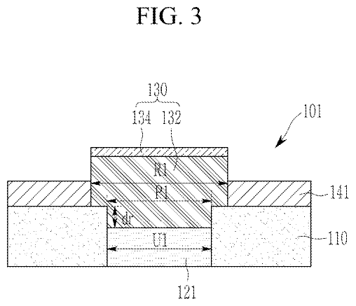

FIGS. 3 to 6 are cross-sectional views illustrating various modified examples of a printed circuit board illustrated in FIG. 1.

The printed circuit board illustrated in FIGS. 3 to 6 basically have the same laminated structure as the printed circuit board 100 illustrated in FIG. 1.

That is, the printed circuit board according to modified examples includes an insulation layer 110 and a first connection pad 121 having a surface embedded in the insulation layer 110. One surface of the first connection pad 121 is disposed to be recessed from the first surface 110a of the insulation layer 110 with a recessed depth dr and the conductive layer 130 including the nickel (Ni) conductive layer 132 and the gold Au conductive layer 134 is plated to be formed on the first connection pad 121. A first solder resist layer 141 is formed on the first surface 110a of the insulation layer 110 and the conductive layer 130 protrudes to be higher than the surface of the first solder resist layer 141.

Hereinafter, different characteristics of the modified examples will be mainly described.

In a printed circuit board 101 illustrated in FIG. 3, an open region P1 of the insulation layer 110 may be formed to be aligned with an upper region U1 of the first connection pad 121 with the same planar area. Further, the open region R1 of the first solder resist layer 141 is formed to be larger than the open region P1 of the insulation layer 110 on both sides of the first surface 110a of the insulation layer 110. Accordingly, a planar area of the nickel conductive layer 132 formed in the open region P1 of the insulation layer 110 may be formed to be the same as a planar area of the upper region U1 of the first connection pad 121. The planar area of the nickel conductive layer 132 formed in the open region R1 of the first solder resist layer 141 may be formed to be larger than the planar area of the nickel conductive layer 132 formed in the open region P1 of the insulation layer 110.

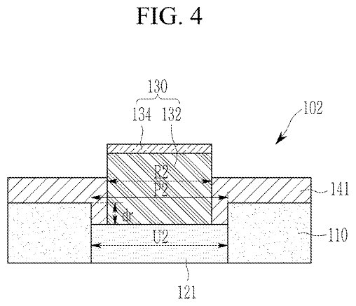

In a printed circuit board 102 illustrated in FIG. 4, an open region P2 of the insulation layer 110 may be formed to be aligned with an upper region U2 of the first connection pad 121 with the same planar area. Further, the open region R2 of the first solder resist layer 141 may be formed to be narrowed with the smaller planar area than that of the open region P2 of the insulation layer 110 on both sides of the first surface 110a of the insulation layer 110. Accordingly, in the open region P2 of the insulation layer 110, a part of the first solder resist layer 141 downwardly expands to form the open region R2 of the first solder resist layer 141. In this case, the planar area of the nickel conductive layer 132 formed in the open region R2 of the first solder resist layer 141 may be formed to be smaller than the planar area of the upper region U2 of the first connection pad 121.

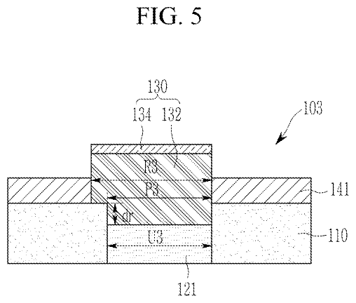

In a printed circuit board 103 illustrated in FIG. 5, an open region P3 of the insulation layer 110 may be formed to be aligned with an upper region U3 of the first connection pad 121 with the same planar area. Further, the open region R3 of the first solder resist layer 141 is formed to be larger than the open region P3 of the insulation layer 110 on one side of the first surface 110a of the insulation layer 110. That is, any one edges of the open region R3 of the first solder resist layer 141 and the open region P3 of the insulation layer 110 are aligned with each other and the other edges are alternately formed. Even though in FIG. 5, an example in which right edges are aligned with each other and left edges are alternately formed from each other, in contrast, the left edges are aligned and the right edges are alternately formed from each other.

Accordingly, a planar area of the nickel conductive layer 132 formed in the open region P3 of the insulation layer 110 may be formed to be the same as a planar area of the upper region U3 of the first connection pad 121. The planar area of the nickel conductive layer 132 formed in the open region R3 of the first solder resist layer 141 may be formed to be larger than the planar area of the nickel conductive layer 132 formed in the open region P3 of the insulation layer 110.

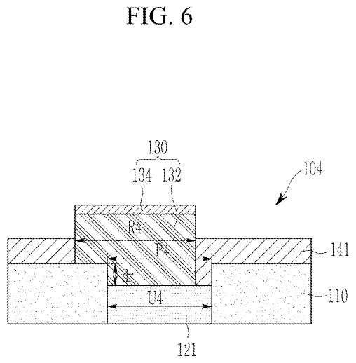

In a printed circuit board 104 illustrated in FIG. 6, an open region P4 of the insulation layer 110 may be formed to be aligned with an upper region U4 of the first connection pad 121 with the same planar area. In this case, an open region R4 of the first solder resist layer 141 may be alternately formed with an open region P4 of the insulation layer 110 on both sides of the first surface 110a of the insulation layer 110. That is, the open region R4 of the first solder resist layer 141 is shifted to one side from the open region P4 of the insulation layer 110. Even though in FIG. 6, an example that the region R4 is shifted to the left, the region R4 may be formed to be shifted to the right.

Accordingly, a planar area of the nickel conductive layer 132 formed in the open region P4 of the insulation layer 110 may be formed to be smaller than a planar area of the upper region U4 of the first connection pad 121. The planar area of the nickel conductive layer 132 formed in the open region R4 of the first solder resist layer 141 may be formed to be larger than the planar area of the nickel conductive layer 132 formed in the open region P4 of the insulation layer 110.

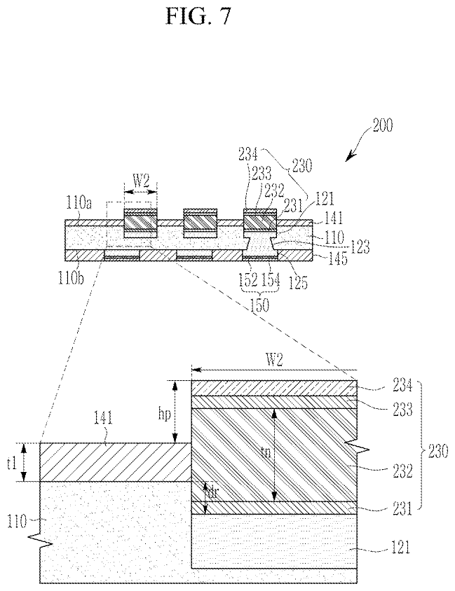

FIG. 7 is a cross-sectional view illustrating a printed circuit board according to another embodiment.

Referring to FIG. 7, a printed circuit board 200 according to the present embodiment includes an insulation layer 110 and a first connection pad 121 embedded in the insulation layer 110. The insulation layer 110 and the first connection pad 121 configure an embedded pattern substrate. The insulation layer 110 and the first connection pad 121 may be configured as the same as the embodiment illustrated in FIG. 1, so that a redundant description will be omitted herein.

A conductive layer 230 is formed on the first connection pad 121 and the conductive layer 230 includes a nickel (Ni) conductive layer 232 and a gold (Au) conductive layer 234 and further includes palladium (Pd) conductive layers 231 and 233 on and below the nickel (Ni) conductive layer 232. Accordingly, the palladium conductive layer 231, the nickel conductive layer 232, and the palladium conductive layer 233 are sequentially formed on the first connection pad 121 and the gold conductive layer 234 is formed on the palladium conductive layer 233. The nickel conductive layer 232 is formed to be thicker than the gold conductive layer 234 and also formed to be thicker than the palladium conductive layers 231 and 233.

In the present embodiment, the conductive layer 230 may be formed by an electroless nickel electroless palladium Immersion gold (ENEPIG) method. That is, the nickel conductive layer 232, the palladium conductive layers 231 and 233, and the gold conductive layer 234 are formed using a method of forming nickel, palladium, and gold metal films on the first connection pad 121 including copper using a chemical reaction.

In this case, a surface of the first solder resist layer 141 is lower than a surface of the conductive layer 230. That is, the conductive layer 230 may protrude to be higher than the surface of the first solder resist layer 141. Further, a protruding thickness hp of the conductive layer 230 may be formed to be larger than a thickness t1 of the first solder resist layer 141.

The nickel conductive layer 232 may be formed to be in contact with the first connection pad 121 with the palladium conductive layer 231 therebetween at a lower height than the first surface 110a of the insulation layer 110. An exposed surface of the first connection pad 121 is disposed to be recessed from the first surface 110a of the insulation layer 110 so that the palladium conductive layer 231 and the nickel conductive layer 232 plated thereon may form an interface with the first connection pad 121 in a lower position than the first surface 110a of the insulation layer 110.

The thickness tn of the nickel conductive layer 232 formed as described above may be larger than a thickness t1 of the first solder resist layer 141. In addition, the nickel conductive layer 232 may protrude to be higher than the surface of the first solder resist layer 141.

In the meantime, when the printed circuit board 200 is seen from the cross-section cut in a thickness direction, a width of the conductive layer 230 may be formed to be the same as a width of the first connection pad 121 at a part where the conductive layer 230 is in contact with the first connection pad 121. Further, a width of a part of the conductive layer 230 which is embedded in the first solder resist layer 141 may be equal to a width of a part of the conductive layer 230 which protrudes from the first solder resist layer 141. Accordingly, the conductive layer 230 may be formed so as not to exceed a width of a part of the conductive layer 230 embedded in the first solder resist layer 141 in a planar direction of the substrate from an upper portion of the first solder resist layer 141.

Specifically, a region which is recessed from the first surface 110a of the insulation layer 110 on the first connection pad 121 with a recessed depth dr and a region formed thereon to form a boundary with the first solder resist layer 141 may be formed to align the interfaces thereof. The palladium conductive layer 231 and the nickel conductive layer 232 are formed in this region and the palladium conductive layer 231 and the nickel conductive layer 232 are formed to have the same width W2 as the first connection pad 121. Further, also in the relationship of the nickel conductive layer 232, the palladium conductive layer 233, and the gold conductive layer 234 which configure the conductive layer 230, the gold conductive layer 234 may be formed to have the same width W2 as the nickel conductive layer 232.

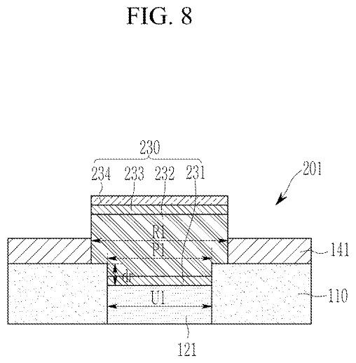

FIGS. 8 to 11 are cross-sectional views illustrating various modified examples of a printed circuit board illustrated in FIG. 7.

The printed circuit boards illustrated in FIGS. 8 to 11 basically have the same laminated structure as the printed circuit board 200 illustrated in FIG. 7.

That is, the f printed circuit boards according to modified examples includes an insulation layer 110 and a first connection pad 121 having a surface embedded in the insulation layer 110. One surface of the first connection pad 121 is disposed to be recessed from the first surface 110a of the insulation layer 110 with a recessed depth dr and the conductive layer 230 including the nickel (Ni) conductive layer 232 and the gold (Au) conductive layer 234 and palladium conductive layer 231 and 233 is formed to be plated on the first connection pad 121. A first solder resist layer 141 is formed on the first surface 110a of the insulation layer 110 and the conductive layer 230 protrudes to be higher than the surface of the first solder resist layer 141.

Hereinafter, differently formed characteristics of the modified examples will be mainly described.

In a printed circuit board 201 illustrated in FIG. 8, an open region P1 of the insulation layer 110 may be formed to be aligned with an upper region U1 of the first connection pad 121 with the same planar area. Further, the open region R1 of the first solder resist layer 141 is formed to be larger than the open region P1 of the insulation layer 110 on both sides of the first surface 110a of the insulation layer 110. Accordingly, planar areas of the palladium conductive layer 231 and the nickel conductive layer 232 formed in the open region P1 of the insulation layer 110 may be formed to be the same as a planar area of the upper region U1 of the first connection pad 121. The planar area of the nickel conductive layer 232 formed in the open region R1 of the first solder resist layer 141 may be formed to be larger than the planar area of the nickel conductive layer 232 formed in the open region P1 of the insulation layer 110.

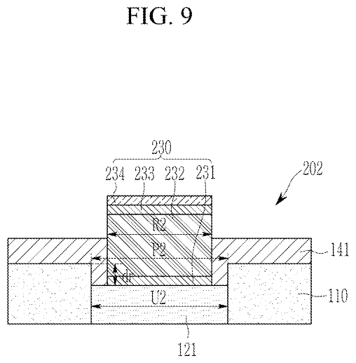

In a printed circuit board 202 illustrated in FIG. 9, an open region P2 of the insulation layer 110 may be formed to be aligned with an upper region U2 of the first connection pad 121 with the same planar area. Further, the open region R2 of the first solder resist layer 141 may be formed to be narrowed with the smaller planar area than that of the open area P2 of the insulation layer 110 on both sides on the first surface 110a of the insulation layer 110. Accordingly, in the open region P2 of the insulation layer 110, a part of the first solder resist layer 141 downwardly expands to form the open region R2 of the first solder resist layer 141. In this case, the planar areas of the palladium conductive layer 231 and the nickel conductive layer 232 formed in the open region R2 of the first solder resist layer 141 may be formed to be smaller than the planar area of the upper region U2 of the first connection pad 121.

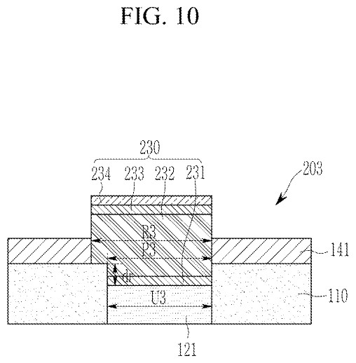

In a printed circuit board 203 illustrated in FIG. 10, an open region P3 of the insulation layer 110 may be formed to be aligned with an upper region U3 of the first connection pad 121 with the same planar area. Further, the open region R3 of the first solder resist layer 141 is formed to be larger than the open region P3 of the insulation layer 110 on one side of the first surface 110a of the insulation layer 110. That is, any one edges of the open region R3 of the first solder resist layer 141 and the open region P3 of the insulation layer 110 are aligned with each other and the other edges are alternately formed. Even though in FIG. 10, an example in which right edges of the region P3 and R3 are aligned with each other and left edges are alternately formed from each other, in contrast, the left edges are aligned and the right edges are alternately formed.

Accordingly, planar areas of the palladium conductive layer 231 and the nickel conductive layer 132 formed in the open region P3 of the insulation layer 110 may be formed to be the same as a planar area of the upper region U3 of the first connection pad 121. The planar area of the nickel conductive layer 232 formed in the open region R3 of the first solder resist layer 141 may be formed to be larger than the planar area of the nickel conductive layer 232 formed in the open region P3 of the insulation layer 110.

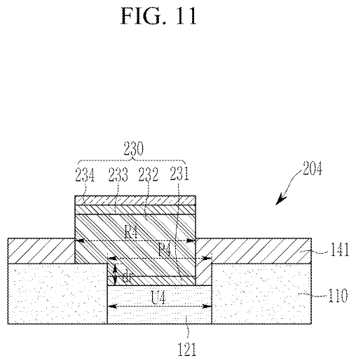

In a printed circuit board 204 illustrated in FIG. 11, an open region P4 of the insulation layer 110 may be formed to be aligned with an upper region U4 of the first connection pad 121 with the same planar area. In this case, an open region R4 of the first solder resist layer 141 may be alternately formed with an open region P4 of the insulation layer 110 on both sides of the first surface 110a of the insulation layer 110. That is, the open region R4 of the first solder resist layer 141 is shifted to one side from the open region P4 of the insulation layer 110. Even though in FIG. 11, an example that the region R4 is shifted to the left, the region R4 may be formed to be shifted to the right.

Accordingly, planar areas of the palladium conductive layer 231 and the nickel conductive layer 232 formed in the open region P4 of the insulation layer 110 may be formed to be smaller than a planar area of the upper region U4 of the first connection pad 121. The planar area of the nickel conductive layer 232 formed in the open region R4 of the first solder resist layer 141 may be formed to be larger than the planar area of the nickel conductive layer 232 formed in the open region P4 of the insulation layer 110.

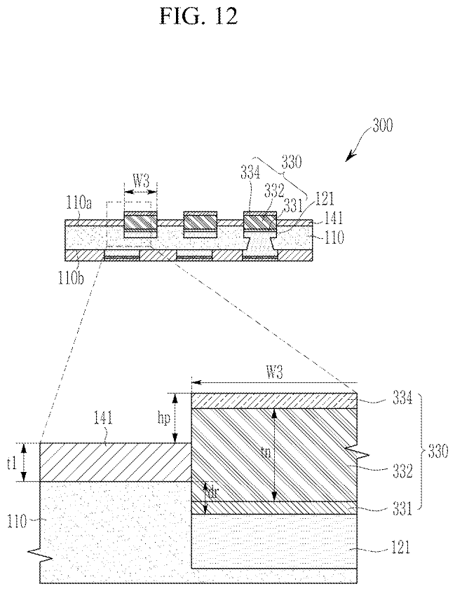

FIG. 12 is a cross-sectional view illustrating a printed circuit board according to still another embodiment.

Referring to FIG. 12, a printed circuit board 300 according to the present embodiment includes an insulation layer 110 and a first connection pad 121 embedded in the insulation layer 110. The insulation layer 110 and the first connection pad 121 configure an embedded pattern substrate. The insulation layer 110 and the first connection pad 121 may be configured as the same as the embodiment illustrated in FIG. 1, so that a redundant description will be omitted herein.

A conductive layer 330 is formed on the first connection pad 121 and the conductive layer 330 includes a nickel (Ni) conductive layer 332 and a gold (Au) conductive layer 334 and further includes a palladium (Pd) conductive layer 331 below the nickel (Ni) conductive layer 332. Accordingly, the palladium conductive layer 331 and the nickel conductive layer 332 are sequentially formed on the first connection pad 121 and the gold conductive layer 334 is formed on the nickel conductive layer 332. The nickel conductive layer 332 is formed to be thicker than the gold conductive layer 334 and also formed to be thicker than the palladium conductive layer 331.

In the present embodiment, the conductive layer 330 may be formed by an electroless nickel Immersion gold (ENIG) method. That is, the nickel conductive layer 332, the palladium conductive layer 331, and the gold conductive layer 334 are formed using a method of forming a metal film by reducing a metal ion from a metal salt solution onto a surface of a member to be plated.

In this case, a surface of the first solder resist layer 141 is lower than a surface of the conductive layer 330. That is, the conductive layer 330 may protrude to be higher than the surface of the first solder resist layer 141. Further, a protruding thickness hp of the conductive layer 330 may be formed to be larger than a thickness t1 of the first solder resist layer 141.

The nickel conductive layer 332 may be formed to be in contact with the first connection pad 121 with the palladium conductive layer 331 therebetween at a lower height than the first surface 110a of the insulation layer 110. An exposed surface of the first connection pad 121 is disposed to be recessed from the first surface 110a of the insulation layer 110 so that the palladium conductive layer 331 and the nickel conductive layer 332 plated thereon may form an interface with the first connection pad 121 in a lower position than the first surface 110a of the insulation layer 110.

The thickness tn of the nickel conductive layer 332 formed as described above may be larger than a thickness t1 of the first solder resist layer 141. In addition, the nickel conductive layer 332 may protrude to be higher than the surface of the first solder resist layer 141.

In the meantime, when the printed circuit board 300 is seen from the cross-section cut in a thickness direction, a width of the conductive layer 330 may be formed to be the same as a width of the first connection pad 121 at a part where the conductive layer 330 is in contact with the first connection pad 121. Further, a width of a part of the conductive layer 330 which is embedded in the first solder resist layer 141 may be equal to a width of a part of the conductive layer 330 which protrudes from the first solder resist layer 141. Accordingly, the conductive layer 330 may be formed so as not to exceed a width of a part of the conductive layer 330 embedded in the first solder resist layer 141 in a planar direction of the substrate from an upper portion of the first solder resist layer 141.

Specifically, a region which is recessed from the first surface 110a of the insulation layer 110 on the first connection pad 121 with a recessed depth dr and a region formed thereon to form a boundary with the first solder resist layer 141 may be formed to align the interfaces thereof. The palladium conductive layer 331 and the nickel conductive layer 332 are formed in this region and the palladium conductive layer 331 and the nickel conductive layer 332 are formed to have the same width W3 as the first connection pad 121. Further, also in the relationship of the nickel conductive layer 332 and the gold conductive layer 334, the gold conductive layer 334 may be formed to have the same width W3 as the nickel conductive layer 332.

In the meantime, the printed circuit board 300 having a laminated structure according to the embodiment illustrated in FIG. 12 also has a modified example with the same structure illustrated in FIGS. 8 to 11. The structure is the same except that the palladium conductive layer is not formed between the nickel conductive layer and the gold conductive layer so that a redundant description will be omitted herein.

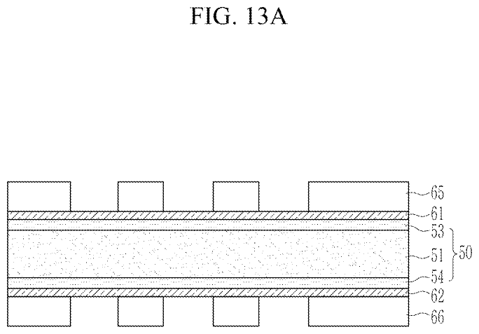

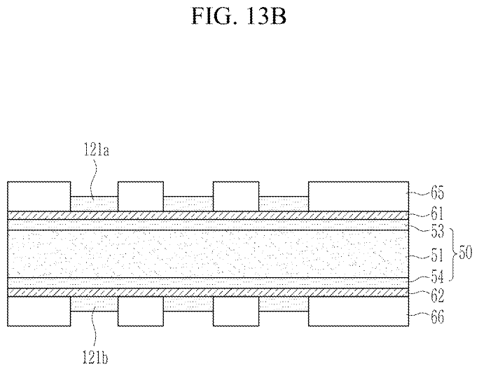

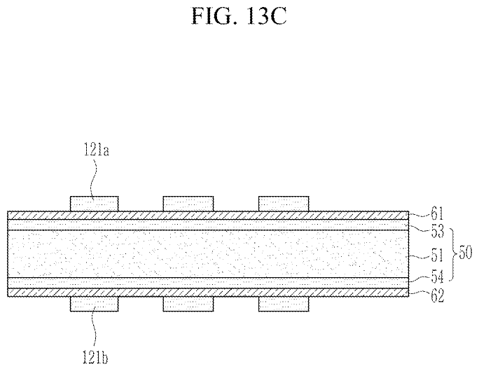

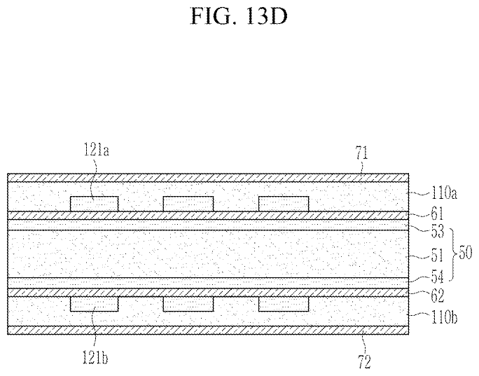

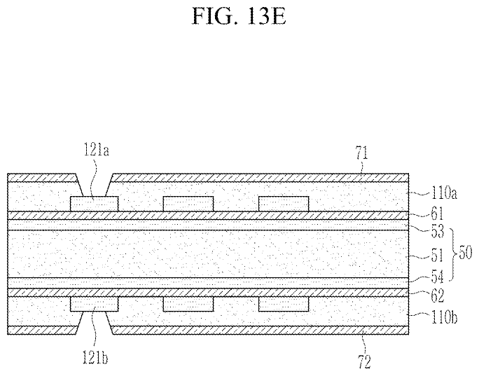

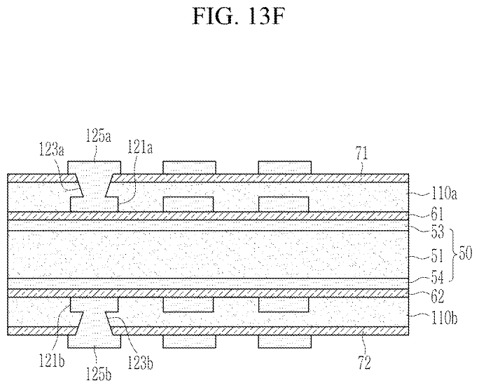

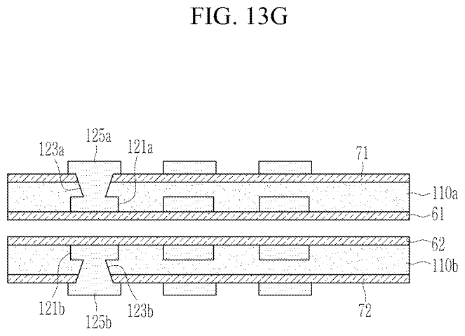

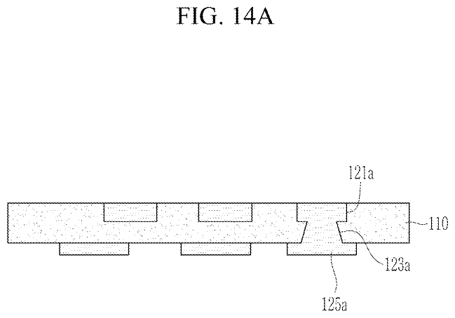

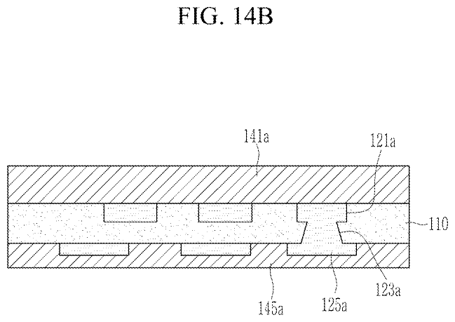

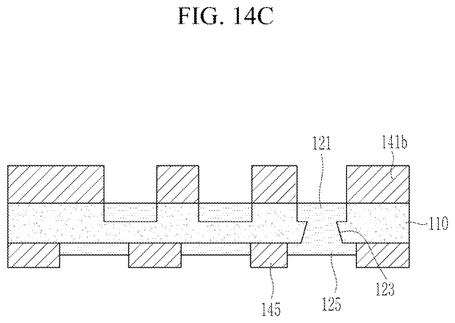

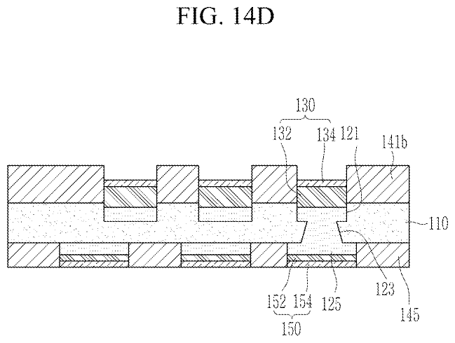

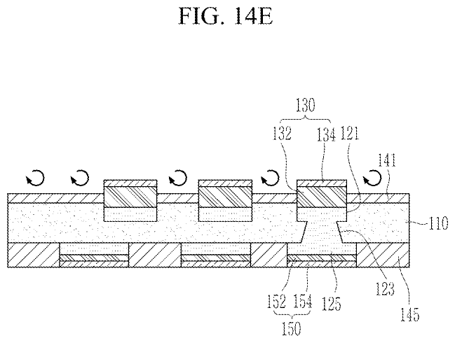

FIGS. 13A to 13G are cross-sectional views illustrating a part of a process for manufacturing a printed circuit board illustrated in FIG. 1 and FIGS. 14A to 14E are cross-sectional views illustrating the other part of a process for manufacturing a printed circuit board illustrated in FIG. 1. A manufacturing method of a printed circuit board according to an embodiment will be described with reference to FIGS. 13A to 13G and FIGS. 14A to 14E together with FIG. 1.

As illustrated in FIGS. 13A to 13C, a carrier substrate 50 on which first seed layers 61 and 62 are laminated is prepared and first circuit pattern layers 121a and 121b are formed on the first seed layers 61 and 62 using a circuit forming process. As the first seed layers 61 and 62, any conductive metal which is used for a circuit in the field of a circuit board may be applied without being limited and generally, copper is used. The carrier substrate 50 is a substrate in which copper foil layers 53 and 54 are laminated on both surfaces of an insulating material 51. The first seed layer 61 and the copper foil layer 53 are separated from each other and the first seed layer 62 and the copper foil layer 54 are separated from each other.

Referring to FIG. 13A, plating resists 65 and 66 are laminated on the carrier substrate 50, exposure and development are performed thereon to form a plated resist pattern from which only a portion where the first circuit pattern layers 121a and 121b are formed is removed.

Referring to FIG. 13B, first circuit pattern layers 121a and 121b for forming a circuit may be formed using the patterned plated resists 65 and 66. The first circuit pattern layers 121a and 121b are plated on the first seed layers 61 and 62 which are exposed through openings of the plating resists 65 and 66 on which a conductive metal is patterned.

The first circuit pattern layers 121a and 121b are connected to the first seed layers 61 and 62 of the carrier substrate 50 and include the same metal as the first seed layers 61 and 62. For example, the first seed layers 61 and 62 and the first circuit pattern layers 121a and 121b include copper (Cu).

Referring to FIG. 13C, after forming the first circuit pattern layers 121a and 121b, the plated resists 65 and 66 are stripped. The plated resists 65 and 66 may be stripped by dissolving and decomposing the plated resists 65 and 66 using a strip solution.

Even though in the present embodiment, it is illustrated that the first circuit pattern layers 121a and 121b are formed on both surfaces of the carrier substrate 50, the first circuit pattern layers 121a and 121b are also formed only on one surface of the carrier substrate 50, which belongs to the scope of the present disclosure.

Referring to FIG. 13D, the insulation layers 110a and 110b are laminated to embed the first circuit pattern layers 121a and 121b and second seed layers 71 and 72 are formed on an upper surface of the insulation layers 110a and 110b. The second seed layers 71 and 72 are formed to perform the electroplating so that any conductive metal may be used without being limited and copper is generally used.

The insulation layers 110a and 110b may include resin insulation layers. The insulation layers 110a and 110b use a thermosetting resin such as epoxy resin, a thermoplastic resin such as polyimide, or a resin impregnated with a reinforcing member such as glass fiber or inorganic filler, for example, prepreg, and also include a thermosetting resin and/or a photocurable resin, but is not limited thereto.

Referring to FIG. 13E, a part of the first circuit pattern layers 121a and 121b is exposed by partially removing the insulation layers 110a and 110b and the second seed layers 71 and 72 to form vias.

Referring to FIG. 13F, an exposed part of the first circuit pattern layers 121a and 121b and the second seed layers 71 and 72 are used as electroplating seed layers to perform the electroplating. By performing the plating process, the second circuit pattern layers 125a and 125b including vias 123a and 123b which are electrically connected to a part of the first circuit pattern layers 121a and 121b are formed. That is, the second circuit pattern layers 125a and 125b are formed by a method similar to the method of forming the first circuit pattern layers 121a and 121b and the second circuit pattern layers 125a, and 125b and the vias 123a and 123b may include the same material as the first circuit pattern layers 121a and 121b. By doing this, embedded pattern substrate parts are completed on both sides of the carrier substrate 50.

According to the illustrated embodiment, even though it is illustrated that each embedded pattern substrate part includes one insulation layer 110a/110b and two metal layers including the first circuit pattern layer 121a/121b and the second circuit pattern layer 125a/125b, it is not limited thereto. Therefore, more insulation layers and more circuit patterns may be included, which belongs to the scope of the present disclosure.

Referring to FIG. 13G, the first seed layers 61 and 62 and copper foil layers 53 and 54 are separated to prepare an embedded pattern substrate. The first seed layers 61 and 62 and copper foil layers 53 and 54 formed on both surfaces of the carrier substrate 50 are separated to obtain a pair of embedded pattern substrates. The process may be individually applied to the pair of embedded pattern substrates.

Hereinafter, a process of performing the process on one embedded pattern substrate will be described with reference to FIGS. 14A to 14E.

Referring to FIG. 14A, the embedded pattern substrate obtained from FIG. 13G is subjected to soft etching to partially remove the first seed layer 61 and the second seed layer 71. That is, the soft etching may remove the entire first seed layer 61 or remove a second seed layer 71 in a region where the second circuit pattern layer 125a is not formed. The embedded pattern substrate illustrated in FIG. 14A is obtained by inverting a substrate formed by separating the first seed layer 61 and the copper foil layer 53 in FIG. 13G. Further, the second circuit pattern layer 125a and the second seed layer 71 include the same material so that the second seed layer 71 is not separately illustrated in the drawings after the soft etching.

After partially removing the first seed layer 61 and the second seed layer 71, a first circuit pattern layer 121a and a second circuit pattern layer 125a embedded in the insulation layer 110 and a via 123a which connects the first circuit pattern layer 121a and the second circuit pattern layer 125a are formed. Thereafter, the first circuit pattern layer 121a configures a first connection pad 121 and the second circuit pattern layer 125a configures a second connection pad 125 (see FIG. 14E).

Referring to FIG. 14B, a first solder resist layer 141a which covers top surfaces of the first circuit pattern layer 121a and the insulation layer 110 and a second solder resist layer 145a which covers bottom surfaces of the second circuit pattern layer 125a and the insulation layer 110 are formed by a solder masking process. In this case, the first solder resist layer 141a may be formed to be thicker than the second solder resist layer 145a.

The solder resist layers 141a and 145a serve as protective layers which protect an outermost circuit and are formed for electrical insulation. The solder resist layers 141a and 145a may be configured by a solder resist ink, a solder resist film, or an encapsulant, for example as known in the art, but is not specifically limited thereto.

Referring to FIG. 14C, solder resist layers 141b and 145 in which a first opening and a second opening are formed are formed in regions corresponding to the first circuit pattern layer 121a and the second circuit pattern layer 125a, respectively, by patterning the solder resist layers 141a and 145a. By doing this, the surfaces of the first circuit pattern layer 121a and the second circuit pattern layer 125a are exposed through the first opening and the second opening.

The solder resister layers 141a and 145a are patterned by exposing and developing the solder resist layers 141a and 145a with a photo resist process to partially remove the solder resist layers 141a and 145a. Surfaces of the first circuit pattern layer 121a and the second circuit pattern layer 125a which are exposed during a process of partially removing the solder resist layers 141a and 145a are partially etched to be recessed from the surface of the insulation layer 110. The first circuit pattern layer 121a and the second circuit pattern layer 125a may configure the first connection pad 121 and the second connection pad 125, respectively.

Referring to FIG. 14D, conductive layers 130 and 150 are formed in the first connection pad 121 and the second connection pad 125 which are exposed through the openings of the solder resist layers 141b and 145. The conductive layers 130 and 150 may be formed by an electrolyte gold plating method. That is, the nickel conductive layer 132 and the gold conductive layer 134 may be formed by applying a current to the first connection pad 121 including copper to form a nickel/gold metal film.

Further, the nickel conductive layer 132 and the gold conductive layer 134 are sequentially formed on the first connection pad 121 and the nickel conductive layer 152 and the gold conductive layer 154 are sequentially formed on the second connection pad 125. In this case, the nickel conductive layer 132 may be formed on the first connection pad 121 to be thicker than the first connection pad 121. The nickel conductive layer 132 formed on the first connection pad 121 may be formed to be higher than the surface of the insulation layer 110 and lower than the surface of the solder resist layer 141b.

Referring to FIG. 14E, the solder resist layer 141b is thinned so that the conductive layer 130 protrudes to be higher than the surface of the thinned first solder resist layer 141. The protruding height of the conductive layer 130 may be larger than the thickness of the first solder resist layer 141.

The solder resist layer may be thinned by a chemical process. The solder resist layer may be thinned by the chemical process according to the following order.

First, the solder resist which is applied, but is not cured is immersed in a chemical etching solution (for example, RT-300 (chemical) to dissociate a part of the solder resist by a chemical treatment. The chemical etching solution substitutes a carboxyl group by inducing a binding between binder polymers of the solder resister to remove reactivity. Accordingly, the photo-crosslinking monomer and the photopolymerization initiator hinders the binding of the carboxyl group of the binder polymer.

Next, the solder resister which is dissociated with the chemical treatment is dissolved with an etching spray (for example, R solution (Spray) to be removed. When the photo-crosslinking monomer and the photopolymerization initiator do not act, the photo-curing is not possible and the micelle binder polymer may be dissolved with the etching spray.

Finally, after the final water rinse, only a part of the solder resist layer remains.

In the meantime, as another example, the thinning of the solder resist layer is also possible by a physical process using laser.

Also, in order to manufacture the printed circuit board illustrated in FIGS. 7 and 12, the process illustrated in FIGS. 13A to 13G is applied and the process illustrated in FIGS. 14A to 14E may be modified to be applied.

That is, when the conductive layer is formed in the process step illustrated in FIG. 14D, the printed circuit board illustrated in FIG. 7 may be manufactured by the Electroless Nickel Electroless Palladium Immersion Gold (ENEPIG) method. That is, the nickel conductive layer 232, the palladium conductive layers 231 and 233, and the gold conductive layer 234 may be formed by a method of forming nickel, palladium, and gold metal films on the first connection pad 121 including copper using a chemical reaction.

Further, when the conductive layer is formed in the process step illustrated in FIG. 14D, the printed circuit board illustrated in FIG. 12 may be manufactured by the electroless ENIG (Electroless Nickel Immersion Gold) method. That is, the nickel conductive layer 332, the palladium conductive layer 331, and the gold conductive layer 334 are formed on a surface of the first connection pad 121 including copper using a method of forming a metal film by reducing a metal ion from a metal salt solution onto a surface of a member to be plated.

### DESCRIPTION OF SYMBOLS

100, 200, 300: Printed circuit board
110: Insulation layer
121: First connection pad
123: Via
125: Second connection pad
130, 150: Conductive layer
132, 152: Nickel conductive layer
134, 154: Gold conductive layer
141: First solder resist layer
145: Second solder resist layer

What is claimed is:

1. A printed circuit board, comprising:
an insulation layer having a first surface and a second surface which are opposite to each other;
a first connection pad which is embedded in the insulation layer and has a surface recessed from the first surface of the insulation layer;
a conductive layer which is located on the first connection pad and has a part embedded in the insulation layer and another part protruding from the first surface of the insulation layer; and
a first solder resist layer which is located on the first surface of the insulation layer and has a surface which is at a level equal to or lower than a surface of the conductive layer.

2. The printed circuit board of claim 1, wherein a side surface of the conductive layer has a part which is in contact with the first solder resist layer.

3. The printed circuit board of claim 1, wherein the conductive layer protrudes from the surface of the first solder resist layer, and a thickness of a part of the conductive layer that protrudes from the surface of the first solder resist layer is larger than a thickness of the first solder resist layer.

4. The printed circuit board of claim 1, wherein the conductive layer further includes a nickel (Ni) conductive layer located on the first connection pad and a gold (Au) conductive layer located on the nickel (Ni) conductive layer, and
the nickel conductive layer is in contact with the first connection pad at a height lower than the first surface of the insulation layer.

5. The printed circuit board of claim 4, wherein a thickness of the nickel conductive layer is larger than a thickness of the first solder resist layer.

6. The printed circuit board of claim 4, wherein the nickel conductive layer protrudes from the surface of the first solder resist layer.

7. The printed circuit board of claim 1, wherein a width of the conductive layer is equal to a width of the first connection pad in a portion where the conductive layer is in contact with the first connection pad.

8. The printed circuit board of claim 1, wherein a width of a part of the conductive layer embedded in the first solder resist layer and a width of a part of the conductive layer protruding from the first solder resist layer are equal to each other.

9. The printed circuit board of claim 8, wherein the conductive layer further includes a nickel (Ni) conductive layer located on the first connection pad and a gold (Au) conductive layer located on the nickel (Ni) conductive layer and
a width of the gold conductive layer is equal to a width of the nickel conductive layer.

10. The printed circuit board of claim 9, wherein the conductive layer further includes a palladium (Pd) conductive layer disposed between the nickel conductive layer and the gold conductive layer, and includes another palladium (Pd) conductive layer disposed between the nickel conductive layer and the first connection pad.

11. The printed circuit board of claim 1, wherein a width of the part of the conductive layer embedded in the insulation layer is smaller than a width of the part of the conductive layer protruding from the first surface of the insulation layer.

12. The printed circuit board of claim 1, wherein a width of the part of the conductive layer protruding from the first surface of the insulation layer increases from both side surfaces of the part of the conductive layer embedded in the insulation layer.

13. The printed circuit board of claim 1, wherein a width of the part of the conductive layer protruding from the first surface of the insulation layer increases from one side surface of the part of the conductive layer embedded in the insulation layer, and
another side surface opposing the one side surface of the part of the conductive layer embedded in the insulation layer is coplanar with a side surface of the part of the conductive layer protruding from the first surface of the insulation layer.

14. The printed circuit board of claim 1, wherein the insulation layer includes a groove adjacent to a side surface of the part of the conductive layer embedded in the insulation layer, and a portion of the first solder resist layer fills a space of the groove.

15. The printed circuit board of claim 1, wherein the insulation layer includes a pair of grooves adjacent to both side surfaces of the part of the conductive layer embedded in the insulation layer, and portions of the first solder resist layer fill spaces of the pair of grooves.

16. The printed circuit board of claim 1, wherein the conductive layer is formed in plural such that the plurality of conductive layers are disposed on the insulation layer to be adjacent to each other, and a portion of the first solder resist layer is disposed between the plurality of adjacent conductive layers.

17. The printed circuit board of claim 1, wherein the first connection pad is a bond finger for a wire bonding pad.

18. The printed circuit board of claim 1, further comprising:
a second connection pad located on the second surface of the insulation layer; and
a second solder resist layer which is disposed in the vicinity of the second connection pad on the second surface of the insulation layer.

19. The printed circuit board of claim 18, wherein the first solder resist layer is thinner than the second solder resist layer.

20. The printed circuit board of claim 18, wherein the insulation layer includes a plurality of insulation layers and each of the plurality of insulation layers includes a circuit layer.

21. The printed circuit board of claim 20, further comprising:
a via which is embedded in the insulation layer to be connected to the circuit layer and extends in a thickness direction of the insulation layer.

22. A manufacturing method of a printed circuit board, comprising:
forming an embedded pattern substrate including a first connection pad embedded in an insulation layer having a first surface and a second surface which are opposite to each other;
forming a first solder resist layer on the first surface of the insulation layer to cover the first connection pad;
patterning a first opening in the first solder resist layer to expose the first connection pad;
forming a conductive layer in the first opening by performing a plating process; and
thinning the first solder resist layer.

23. The manufacturing method of the printed circuit board of claim 22, wherein the thinning of the first solder resist layer includes:
protruding the conductive layer from a surface of the first solder resist layer.

24. The manufacturing method of the printed circuit board of claim 23, wherein a thickness of a part of the conductive layer that protrudes from the surface of the first solder resist layer is formed to be larger than a thickness of the first solder resist layer.

25. The manufacturing method of the printed circuit board of claim 22, wherein the forming of a conductive layer includes:
forming a nickel (Ni) conductive layer on the first connection pad; and
forming a gold (Au) conductive layer on the nickel conductive layer.

26. The manufacturing method of the printed circuit board of claim 25, wherein the thinning of the first solder resist layer includes:
making a thickness of the nickel conductive layer larger than a thickness of the first solder resist layer.

27. The manufacturing method of the printed circuit board of claim 25, wherein the thinning of the first solder resist layer further includes:
protruding the nickel conductive layer from the surface of the first solder resist layer.

28. The manufacturing method of the printed circuit board of claim 22, wherein the pattering of the first opening on the first solder resist layer includes:
forming a plurality of first openings to be adjacent to each other.

29. A printed circuit board, comprising:
an insulation layer having a first surface and a second surface which are opposite to each other;
a first solder resist layer disposed on the first surface of the insulation layer;
a first connection pad embedded in the insulation layer; and
a conductive layer including a nickel (Ni) conductive layer disposed on the first connection pad and a gold (Au) conductive layer disposed on the nickel (Ni) conductive layer,
wherein at least portions of the nickel (Ni) conductive layer and the gold (Au) conductive layer protrude from an upper surface of the first solder resist layer.

30. The printed circuit board of claim 29, wherein an upper surface of the first connection pad is recessed from the first surface of the insulation layer.

31. The printed circuit board of claim 30, wherein at least a portion of the first solder resist layer is disposed between an inner surface of a recess of the insulation layer and a side surface of the nickel (Ni) conductive layer.

32. The printed circuit board of claim 29, wherein the nickel (Ni) conductive layer includes a first portion embedded in the insulation layer and a second portion protruding from the first surface of the insulation layer, and
a width of the first portion of the nickel (Ni) conductive layer is less than or equal to a width of the second portion of the nickel (Ni) conductive layer, where each width is measured in a direction orthogonal to a stacking direction.

33. A printed circuit board, comprising:
an insulation layer having a first surface and a second surface which are opposite to each other;
a first connection pad embedded in the insulation layer;
a second connection pad disposed on the second surface of the insulation layer and connected to the first connection pad through a via;
a first conductive layer disposed on the first connection pad;
a second conductive layer disposed on the second connection pad;
a first solder resist layer disposed on the first surface of the insulation layer; and
a second solder resist layer disposed on the second surface of the insulation layer,
wherein at least a portion of a side surface of the first conductive layer is exposed from an upper surface of the first solder resist layer.

34. The printed circuit board of claim 33, wherein no portion of a side surface of the second conductive layer is exposed from a lower surface of the second solder resist layer.

35. The printed circuit board of claim 33, wherein each of the first and second conductive layers comprises a nickel (Ni) conductive layer disposed on the first connection pad and a gold (Au) conductive layer disposed on the nickel (Ni) conductive layer, and
a portion of the nickel (Ni) conductive layer is embedded in the insulation layer and another portion of the nickel (Ni) conductive layer protrudes from the upper surface of the first solder resist layer.

36. The printed circuit board of claim 35, wherein a thickness of the nickel (Ni) conductive layer of the first conductive layer is greater than a thickness of the nickel (Ni) conductive layer of the second conductive layer, where each thickness is measured in a stacking direction.

37. The printed circuit board of claim 33, wherein a width of the first conductive layer is smaller than a width of the second conductive layer, where each width is measured in a direction orthogonal to a stacking direction.

38. The printed circuit board of claim 33, wherein a thickness of the first solder resist layer is smaller than a thickness of the second solder resist layer, where each thickness is measured in a stacking direction.
